(19) United States
(12) Patent Application Publication
(10) Pub. No.: US 2019/0186002 A1
(43) Pub. Date: Jun. 20, 2019

(54) Solid Precursor, Apparatus for Supplying Source Gas and Deposition Device Having the Same

(71) Applicant: Samsung Electronics Co., Ltd., Suwon-si (KR)

(72) Inventors: Hasan Musarrat, Hwaseong-si (KR); So Young Lee, Hwaseong-si (KR); Ik Soo Kim, Hwaseong-si (KR); Jang Hee Lee, Hwaseong-si (KR)

(21) Appl. No.: 16/019,907

(22) Filed: Jun. 27, 2018

(30) Foreign Application Priority Data
Dec. 15, 2017 (KR) 10-2017-0173486

(51) Int. Cl. C23C 16/448; C23C 16/455

(52) U.S. Cl. CPC C23C 16/4481; C23C 16/45561; C23C 16/45544; C23C 16/45553

(57) ABSTRACT

A source gas supply unit includes a canister including a precursor accommodating space therein, and an inflow surface and an outflow surface which are open. The source gas supply unit includes a first lid configured to seal the inflow surface of the canister and having a gas inlet connected to the precursor accommodating space and a second lid configured to seal the outflow surface of the canister and having a gas outlet connected to the precursor accommodating space. The source gas supply unit includes a ring-shaped solid precursor located in the precursor accommodating space and including a gas flow path therein, which communicates with the gas inlet and the gas outlet. A cross-sectional area of the gas flow path increases from the inflow surface of the canister toward the outflow surface thereof.

### CROSS-REFERENCE TO RELATED APPLICATION

This U.S. non-provisional patent application claims priority under 35 U.S.C. § 119 to and the benefit of Korean Patent Application No. 10-2017-0173486, filed on Dec. 15, 2017, in the Korean Intellectual Property Office (KIPO), the disclosure of which is incorporated herein by reference in its entirety.

### FIELD

The present inventive concept relates to an apparatus for delivering a solid precursor and a delivery system.

### BACKGROUND

Chemical vapor deposition (CVD) or atomic layer deposition (ALD) is a technique for forming a thin film on a semiconductor substrate. Thin film forming techniques may be used for forming metal contacts having high aspect ratios, oxide spacers, high-k metal gates, or the like. Thin films may be formed by supplying a precursor and a reaction gas onto a substrate. The precursor is supplied onto the substrate along with a carrier gas by vaporizing a liquid or solid state material stored in a canister. When a solid precursor is used, a pressure of a carrier gas may be reduced by a space resulting from consumption of the solid precursor. When a pressure of a gas is reduced, a sublimation amount of a precursor may be reduced or a deposition rate of a thin film may be reduced. There is a method of increasing a temperature of a gas to prevent reduction of a pressure of the gas, but there may be a problem in a semiconductor manufacturing process under a high temperature condition. Therefore, there is a need for a technique in which a solid precursor in a canister and a gas flow path are appropriately set without raising a temperature.

### SUMMARY

The present inventive concept is directed to providing a source gas supply unit for compensating for reduction of a sublimation amount of a precursor due to reduction of a pressure of a carrier gas.

An source gas supply unit according to an embodiment of the present inventive concept includes a canister including a precursor accommodating space therein, and an inflow surface and an outflow surface which are open, a first lid including a gas inlet connected to the precursor accommodating space, wherein the first lid is configured to seal the inflow surface of the canister, a second lid including a gas outlet connected to the precursor accommodating space, wherein the second lid is configured to seal the outflow surface of the canister, and a ring-shaped solid precursor disposed in the precursor accommodating space, wherein the ring-shaped solid precursor includes a gas flow path therein in communication with the gas inlet and the gas outlet. A cross-sectional area of the gas flow path varies from the inflow surface of the canister toward the outflow surface thereof.

An source gas supply unit according to an embodiment of the present inventive concept includes a canister including a precursor accommodating space therein, and an inflow surface and an outflow surface which are open, a first lid including a gas inlet connected to the precursor accommodating space, wherein the first lid is configured to seal the inflow surface of the canister, a second lid including a gas outlet connected to the precursor accommodating space, wherein the second lid is configured to seal the outflow surface of the canister, and a ring-shaped solid precursor disposed in the precursor accommodating space, wherein the ring-shaped solid precursor includes at least one gas flow path therein in communication with the gas inlet and the gas outlet. The at least one gas flow path has a cylindrical shape, an inflow surface of the ring-shaped solid precursor faces an inner side of the gas inlet, an outflow surface of the ring-shaped solid precursor faces an inner side of the gas outlet, and cross-sectional areas of the inner sides of the gas inlet and the gas outlet are formed to be greater than a cross-sectional area of the at least one gas flow path so that the inflow surface and the outflow surface of the ring-shaped solid precursor are exposed to a carrier gas.

A deposition device according to an embodiment of the present inventive concept includes an source gas supply unit according to one of embodiments of the present inventive concept, a processing chamber configured to accommodate a substrate, an source gas supply unit configured to supply a precursor to the processing chamber, a carrier gas supply configured to supply a carrier gas to source gas supply unit, and a reaction gas supply configured to supply a reaction gas to the processing chamber.

A ring-shaped solid precursor for thin-film deposition according to an embodiment of the present inventive concept includes a gas flow path therein, wherein the gas flow path has a shape in which a cross-sectional area thereof varies from an inflow surface of the ring-shaped solid precursor to an outflow surface thereof.

### BRIEF DESCRIPTION OF THE DRAWINGS

FIG. 1 is a schematic diagram for describing a precursor delivery system according to an embodiment of the present inventive concept.

FIGS. 2A and 2B are cross-sectional views for describing source gas supply units according to embodiments of the present inventive concept.

FIGS. 3 and 4 are cross-sectional views of source gas supply unit s according to embodiments of the present inventive concept.

FIGS. 5A and 5B are a cross-sectional view and a partially enlarged view of a source gas supply unit according to an embodiment of the present inventive concept.

FIGS. 6 and 7 are cross-sectional views of source gas supply units according to embodiments of the present inventive concept.

FIG. 8 is a schematic diagram for describing a precursor delivery system according to an embodiment of the present inventive concept.

FIG. 9 is a flowchart for describing a method of forming a thin film by delivering a precursor.

### DETAILED DESCRIPTION OF EXEMPLARY EMBODIMENTS

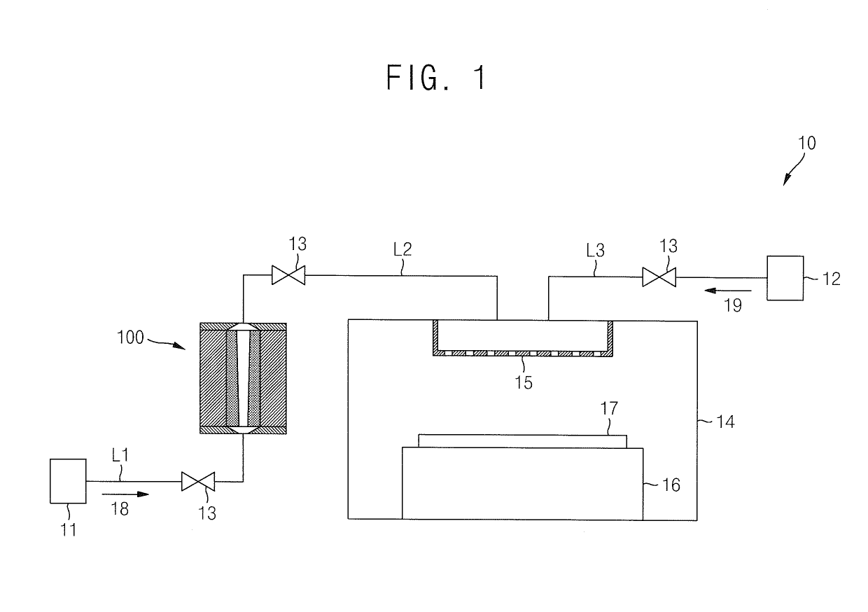

FIG. 1 is a schematic diagram for describing a precursor delivery system 10 according to an embodiment of the present inventive concept.

Referring to FIG. 1, in the embodiment of the present inventive concept, the precursor delivery system 10 may include a carrier gas supply 11, a reaction gas supply 12, gate valves 13, a processing chamber 14, first to third supply lines L1, L2, and L3, and a source gas supply unit 100.

The source gas supply unit 100 may include a solid precursor 120. A carrier gas 18 supplied to the source gas supply unit 100 may sublimate the solid precursor 120 to generate a gaseous precursor. A mixed gas in which a gaseous precursor is contained in the carrier gas 18 may be provided to the processing chamber 14.

The carrier gas supply 11 may provide the carrier gas 18 to the source gas supply unit 100. The carrier gas 18 may include an inert gas such as nitrogen (N₂), argon (Ar), helium (He), or the like. The carrier gas 18 may have a high temperature within a range in which the solid precursor 120 is not thermally decomposed. The heated carrier gas 18 may sublimate the solid precursor 120 into a gaseous state.

The reaction gas supply 12 may provide a reaction gas 19 to the processing chamber 14. The reaction gas 19 may include ammonia (NH₃), water (H₂O), ozone (O₃), or the like.

The processing chamber 14 may include a chemical vapor deposition (CVD) device or an atomic layer deposition (ALD) device. The processing chamber 14 may include a shower head assembly 15, a susceptor 16, and a substrate 17. The shower head assembly 15 may be formed in an upper portion of the processing chamber 14. The shower head assembly 15 may include a plurality of shower heads. The shower head assembly 15 may uniformly provide the carrier gas 18 or the reaction gas 19 supplied into the processing chamber 14 onto the substrate 17. The susceptor 16 may be formed in a lower portion of the processing chamber 14, and the substrate 17 may be formed on the susceptor 16. The processing chamber 14 may include a sealing member (not illustrated) and may form a closed space.

The mixed gas or the reaction gas 19 may be supplied into the processing chamber 14. The carrier gas 18 or the reaction gas 19 supplied into the processing chamber 14 may be provided onto the substrate 17. A purge gas may be supplied into the processing chamber 14 through a purge gas supply (not illustrated). The purge gas may include an inert gas such as nitrogen (N₂), argon (Ar), helium (He), or the like. The carrier gas 18, the purge gas, and the reaction gas 19 may be supplied into the processing chamber 14 one by one in each unit cycle with a constant period. For example, the gases may be supplied into the processing chamber 14 in order from the carrier gas 18, the purge gas, the reaction gas 19, and the purge gas with specific time intervals.

The first supply line L1 may connect the carrier gas supply 11 to the source gas supply unit 100. The carrier gas 18 may be supplied to the source gas supply unit 100 through the first supply line L1. The second supply line L2 may connect the source gas supply unit 100 to the processing chamber 14. The carrier gas 18 containing the gaseous precursor may be supplied into the processing chamber 14 through the second supply line L2. The third supply line L3 may connect the reaction gas supply 12 to the processing chamber 14. The reaction gas 19 may be supplied into the processing chamber 14 through the third supply line L3 in a different route from the carrier gas 18. The gate valves 13 may adjust flow rates of the gases flowing through the first to third supply lines L1, L2, and L3.

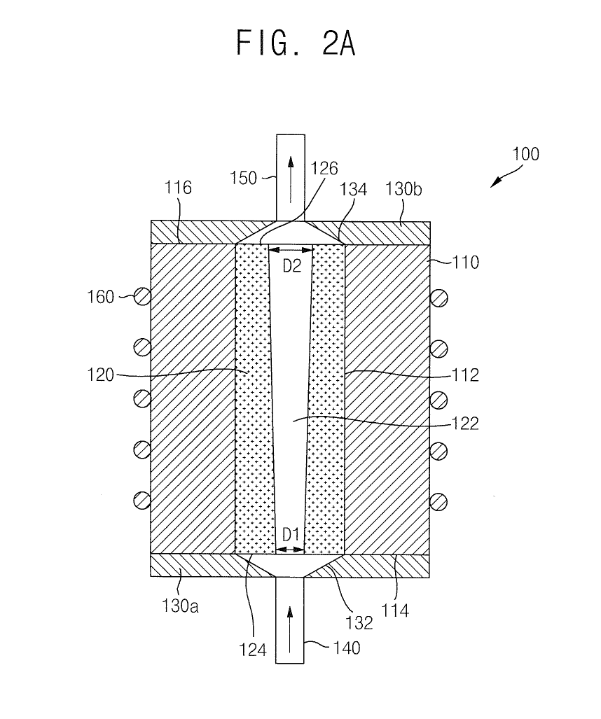

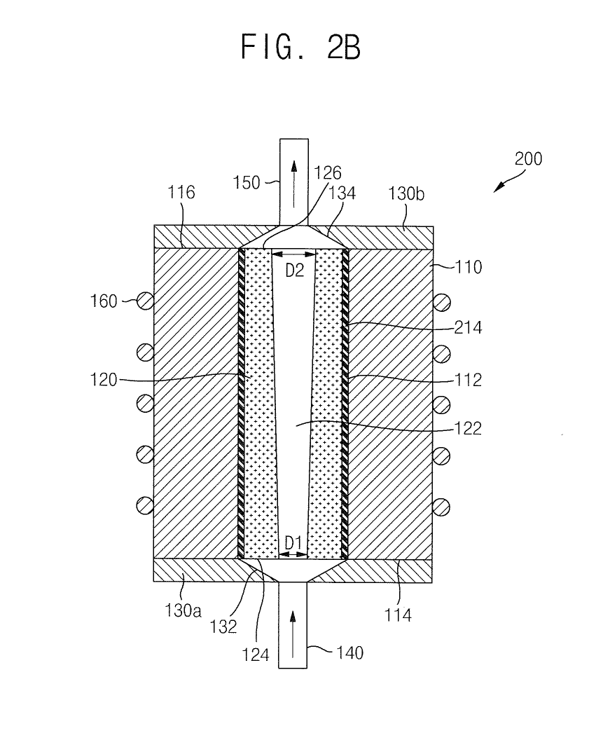

Referring to FIG. 2A, in an embodiment of the present inventive concept, the source gas supply unit 100 may include a canister 110, a solid precursor 120, lids 130a and 130b, a gas inlet 132, a gas outlet 134, a gas inlet pipe 140, a gas outlet pipe 150, and heaters 160.

The canister 110 may have a cylindrical shape, but the present inventive concept is not limited thereto. An inflow surface 114 and an outflow surface 116 of the canister 110 may be open, and a precursor accommodating space 112 may be formed inside the canister 110. Here, the inflow surface 114 and the outflow surface 116 of the canister 110 may be defined as a lower surface and an upper surface of the canister 110 in FIG. 2A, respectively. The precursor accommodating space 112 may be formed to have a shape extending in an axial direction of the canister 110. In other words, the precursor accommodating space 112 may be formed in parallel to a movement direction of the carrier gas 18 supplied to the source gas supply unit 100.

The solid precursor 120 may be disposed in the precursor accommodating space 112 of the canister 110. The solid precursor 120 may have a hollow therein to allow the carrier gas 18 to pass therethrough. The solid precursor 120 may be formed in the precursor accommodating space 112 in a ring shape by a compressing method or the like.

The solid precursor 120 may be a precursor such as tantalum (Ta), lanthanum (La), tungsten (W), molybdenum (Mo), cobalt (Co), or the like, and may include Ta[(N(CH3)₂]₅(PDMAT), TaCl₅, TaF₅, TaBr₅, TaI₅, Ta(CO)₅W(CO)₆, Mo(CO)₆, MoF₅, Co₂(CO)₈, or the like.

A gas flow path 122 may be formed inside the solid precursor 120. The gas flow path 122 may communicate with the gas inlet 132 and the gas outlet 134. The gas flow path 122 may guide the carrier gas 18 being introduced into the canister 110.

Generally, in the precursor delivery system 10, the solid precursor 120 may be eroded by sublimation as a precursor delivery process is repeatedly performed by the carrier gas 18. An erosion amount of the solid precursor 120 at the gas inlet 132 may be greater than an erosion amount of the solid precursor 120 at the gas outlet 134. Since a volume of the gas flow path 122 is increased by an amount of the solid precursor 120 eroded, a pressure of the carrier gas 18 may be reduced. Due to the reduction of the pressure of the carrier gas 18, a sublimation amount of the solid precursor 120 may be reduced.

Referring again to FIG. 2A, diameters D1 and D2 of the gas flow path 122 may be increased due to the erosion of the solid precursor 120 so that the volume of the gas flow path 122 may be increased. In addition, a contact area between the gas flow path 122 and the carrier gas 18 may be increased. The increased contact area may compensate for the reduction of the sublimation amount of the solid precursor 120.

A cross-sectional area of the gas flow path 122 at the gas inlet 132 may be formed to be relatively narrow. Here, the cross-sectional area of the flow path may be defined as a cross-sectional area of the gas flow path 122 in a direction perpendicular to an axial direction of the canister 110. The narrow cross-sectional area of the flow path may compensate for a high erosion amount of the solid precursor 120 at the gas inlet 132.

When the canister 110 has a cylindrical shape, the diameter D1 of the gas flow path 122 at the inflow surface 114 of the canister 110 may be smaller than the diameter D2 of the gas flow path 122 at the outflow surface 116. For example, the gas flow path 122 may be formed to be gradually widened from the inflow surface 114 of the canister 110 toward the outflow surface 116 thereof. Since the diameter D1 is smaller than the diameter D2, the cross-sectional area of the flow path at the gas inlet 132 is narrow, and thus effects described above may be obtained. As the deposition process is repeatedly performed, the solid precursor 120 may be eroded such that a difference between the diameter D1 and the diameter D2 is reduced or the diameter D1 and the diameter D2 are substantially equal.

In an embodiment, a cross-sectional area of the precursor may be formed to be decreased from the inflow surface 114 of the canister 110 to the outflow surface 116 thereof. Here, the cross-sectional area of the precursor may be defined as an area of a cross section of the solid precursor 120 in a direction perpendicular to the axial direction of the canister 110. For example, the solid precursor 120 may be formed such that an inflow surface 124 thereof is wider than an outflow surface 126 thereof. Since the inflow surface 124 of the solid precursor 120 is wide, a high erosion amount at the gas inlet 132 may be compensated.

The lids 130a and 130b may be provided at both ends of the canister 110 to cover the inflow surface 114 and the outflow surface 116 of the canister 110. The lids 130a and 130b may seal the canister 110 so that the solid precursor 120 does not leak. The lids 130a and 130b may be fastened to the canister 110 by a coupling device (not illustrated). In addition, the lids 130a and 130b may be separated so that the solid precursor 120 may be replaced or the canister 110 may be cleaned. The gas inlet 132 may be formed in a first lid 130a and the gas outlet 134 may be formed in a second lid 130b.

The gas inlet 132 may be connected to the gas inlet pipe 140, and the gas outlet 134 may be connected to the gas outlet pipe 150. The gas inlet 132 or the gas outlet 134 may be formed such that an inner side thereof is wider than an outer side thereof. Here, the inner side of the gas inlet 132 or the gas outlet 134 may refer to a surface facing the solid precursor 120, and the outer side thereof may refer to a surface facing the gas inlet pipe 140 or the gas outlet pipe 150.

The inner side of the gas inlet 132 or the gas outlet 134 may correspond to the inflow surface 124 or the outflow surface 126 of the solid precursor 120. The gas inlet 132 and the gas outlet 134 may guide movement of the carrier gas 18.

One end of the gas inlet pipe 140 may be connected to the first supply line L1. The other end of the gas inlet pipe 140 may be connected to the gas inlet 132. The gas inlet pipe 140 may provide the carrier gas 18 supplied from the carrier gas supply 11 into the canister 110.

One end of the gas outlet pipe 150 may be connected to the second supply line L2. The other end of the gas outlet pipe 150 may be connected to the gas outlet 134. The gas outlet pipe 150 may supply the carrier gas 18 passing through the source gas supply unit 100 to the processing chamber 14. The carrier gas 18, which passes through the canister 110 and is discharged through the gas outlet pipe 150, may be saturated with a precursor vapor which is sublimated.

The heaters 160 may be disposed on an outer circumferential surface of the canister 110. The heaters 160 may heat the canister 110 to heat the solid precursor 120 in the canister 110. The solid precursor 120 may be heated by the heaters 160 within a range in which the solid precursor 120 is not thermally decomposed, so as to maintain a temperature required to be sublimated. The heaters 160 may be located inside the canister 110 or may be adjusted by a temperature controller (not illustrated).

FIG. 2B is a cross-sectional view of an source gas supply unit 200 as another embodiment of the source gas supply unit 100 of FIG. 2A.

Referring to FIG. 2B, in the source gas supply unit 200, a canister 110 may further include a support container 214. The support container 214 may be located in a precursor accommodating space 112, and may be formed to surround an outer circumferential surface of a solid precursor 120. The support container 214 may facilitate an arrangement of the solid precursor 120 into the precursor accommodating space 112. For example, the solid precursor 120 may be compressed and disposed on an inner circumferential surface of the support container 214 and then disposed in the precursor accommodating space 112 of the canister 110. When the solid precursor 120 is replaced or the canister 110 is cleaned, the support container 214 may be separated from the canister 110.

The support container 214 may be integrally formed within the precursor accommodating space 112, and may be formed by a plurality of support containers 214 being stacked. The plurality of support containers 214 to be stacked may form a gas flow path 122 in parallel to an axial direction of the canister 110.

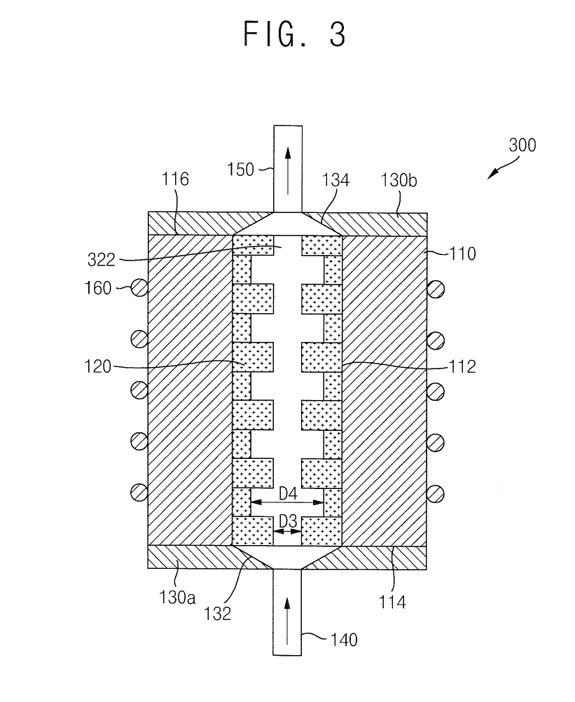

FIG. 3 is a cross-sectional view of a source gas supply unit 300 according to an embodiment of the present inventive concept.

Referring to FIG. 3, a gas flow path 322 formed on an inner circumferential surface of a solid precursor 120 may have different diameters D3 and D4. A ring-shaped trench may be formed in the gas flow path 322 in a direction perpendicular to a movement direction of a carrier gas 18. The trench may have a diameter D4, and the diameter D4 may be greater than the diameter D3. The gas flow path 322 may be formed by a portion having the diameter D3 and a portion having the diameter D4 being alternately stacked.

The gas flow path 322 may be formed to have a wider surface area than a gas flow path having a straight route. A contact area of the carrier gas 18 passing through the gas flow path 322 with the solid precursor 120 may be increased and a contact time may be increased. The carrier gas 18 may sublimate more solid precursors 120 for a sufficiently long contact time. The carrier gas 18 discharged to a gas outlet 134 may supply more precursors to the processing chamber 14.

In an embodiment, a cross-sectional area of a flow path at the gas outlet 134 may be wider than a cross-sectional area of a flow path at a gas inlet 132. The cross-sectional area of the flow path may be gradually widened toward the gas outlet 134.

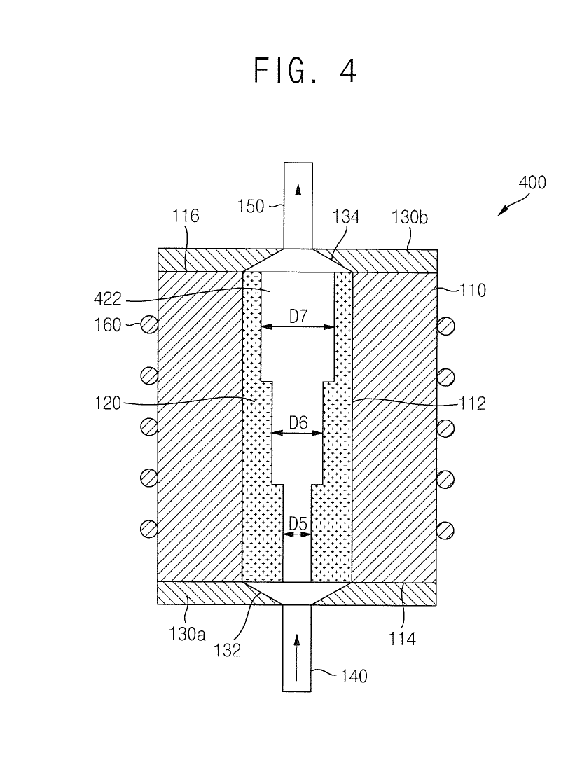

FIG. 4 is a cross-sectional view of source gas supply unit 400 according to an embodiment of the present inventive concept.

Referring to FIG. 4, a gas flow path 422 formed inside a solid precursor 120 may have a diameter D5, a diameter D6, and a diameter D7. The diameter D6 may be greater than the diameter D5, and the diameter D7 may be greater than the diameter D6. A cross-sectional area of the gas flow path 422 may be increased stepwise from an inflow surface 114 of a canister 110 toward an outflow surface 116 thereof.

The gas flow path 422 formed by the diameters D5, D6, and D7 may be relatively narrow at a gas inlet 132, and may compensate for a high erosion amount of a precursor at the gas inlet 132. In addition, since the solid precursor 120 has a stepwise winding surface, a surface area thereof may be further widened. A contact area of the solid precursor 120 with a carrier gas 18 may be increased so that more solid precursors 120 may be sublimated by the carrier gas 18 and transported.

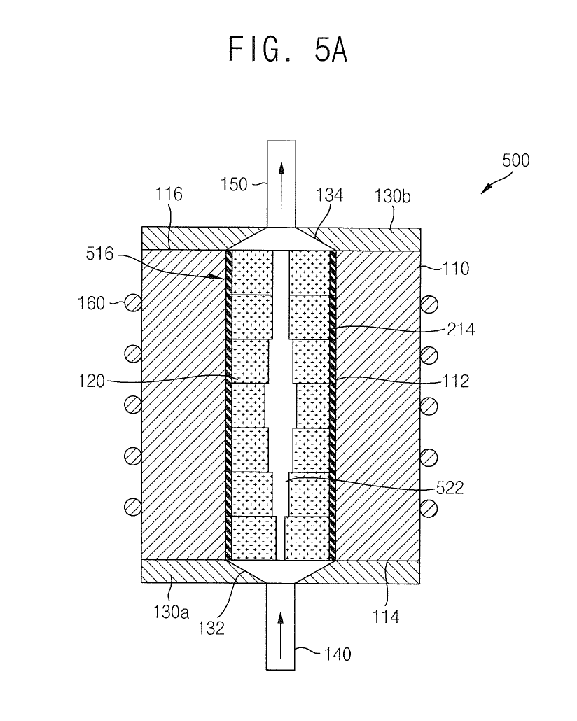

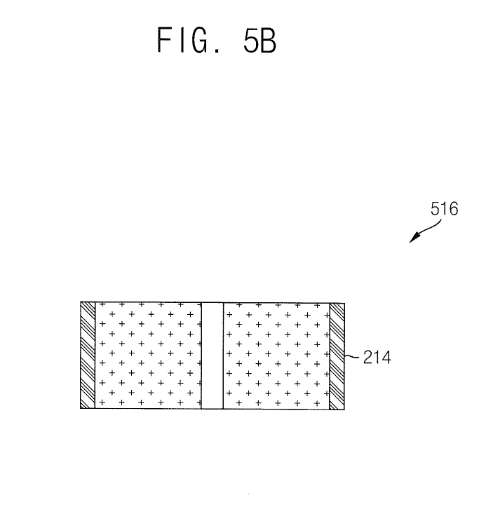

FIG. 5A is a cross-sectional view of source gas supply unit 500 according to an embodiment of the present inventive concept, and FIG. 5B is a partially enlarged view of FIG. 5A.

Referring to FIGS. 5A and 5B, in a precursor accommodating space 112 of a canister 110, a support container 214 may be formed in the form in which unit blocks 516 are stacked. A hollow 518 having a predetermined flow path cross-sectional area may be formed in each of the unit blocks 516. A gas flow path 522 may be formed by the hollows 518 of the unit blocks 516 being stacked in parallel to an axial direction of the canister 110. The gas flow path 522 may guide movement of the carrier gas 18.

Each of the hollows 518 may have a different flow path cross-sectional area or diameter. In addition, a diameter of the gas flow path 522 formed by the hollows 518 being stacked may vary according to a movement direction of the carrier gas 18. For example, the diameter of the gas flow path 522 may be increased from an inflow surface 124 of a solid precursor 120 toward an outflow surface 126 thereof. In addition, the diameter of the gas flow path 522 may be increased from the inflow surface 124 to a predetermined position in the axial direction of the canister 110, and may be decreased to the outflow surface 126. A structure in which the gas flow path 522 is narrow on the inflow surface 124 of the solid precursor 120 may compensate for a large erosion amount of the solid precursor 120 at a gas inlet 132. A structure in which the gas flow path 522 is narrow on the outflow surface 126 of the solid precursor 120 may prevent pressure reduction in a gas outlet pipe 150.

Since the unit blocks 516 are stacked to form the gas flow path 522, the gas flow path 522 may be easily changed according to process conditions. Since the solid precursor 120 is disposed in the unit blocks 516, an arrangement or replacement of the solid precursor 120 may be facilitated.

A shape of the gas flow path 522 is not limited to that illustrated in FIG. 5A. The unit block 516 may have two or more hollows 518. The stacked unit blocks 516 may form two or more gas flow paths 522.

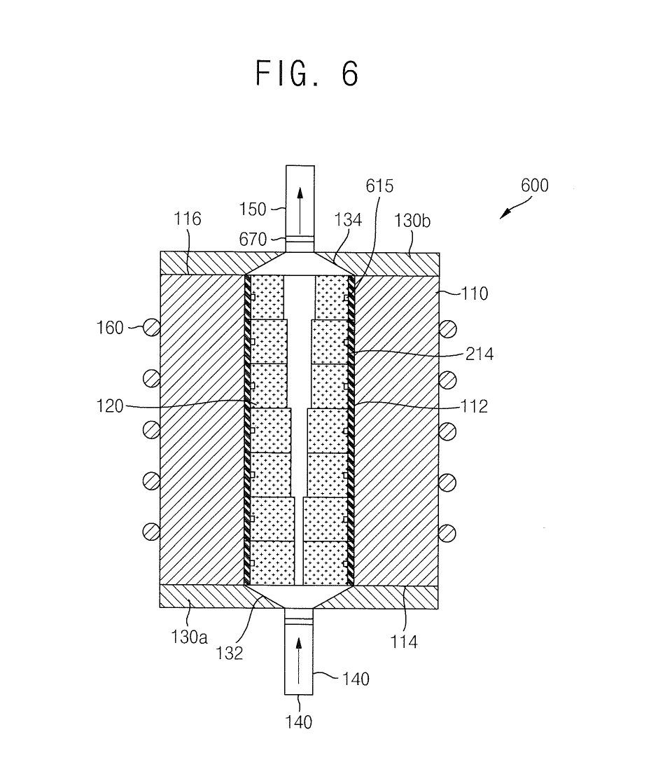

FIG. 6 is a cross-sectional view of a source gas supply unit 600 according to an embodiment of the present inventive concept.

Referring to FIG. 6, a unit block 516 of a canister 110 may include a supporting member 615. Each of a gas inlet pipe 140 and a gas outlet pipe 150 may include a filter 670. The supporting member 615 may be formed on an inner wall of the unit block 516. Four supporting members 615 may be formed along an inner circumferential surface of the unit block 516, but the present inventive concept is not limited thereto.

The supporting member 615 may couple a solid precursor 120 formed by compressing to the unit block 516 so as not to be separated from the unit block 516. A holder (not illustrated) for fixing the unit block 516 or the solid precursor 120 so as not to be discharged to an outside of a precursor accommodating space 112 may be formed in the canister 110.

The filter 670 may be formed to have the same diameter as that of each of the gas inlet pipe 140 and the gas outlet pipe 150. The filter 670 may prevent a mass of un-sublimated solid precursors 120 from being discharged to the gas inlet pipe 140 or the gas outlet pipe 150.

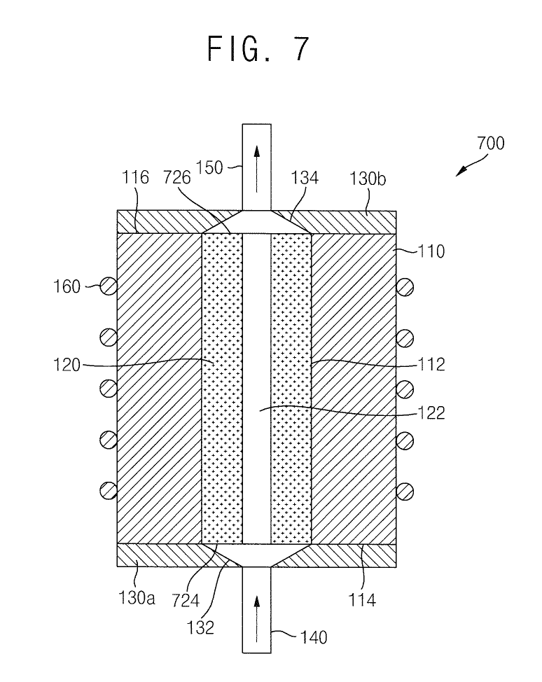

FIG. 7 is a cross-sectional view of a source gas supply unit 700 according to an embodiment of the present inventive concept.

Referring to FIG. 7, an inflow surface 724 of a solid precursor 120 may be exposed to a carrier gas 18 which moves through a canister 110. An outflow surface 726 of the solid precursor 120 may have the same shape as that of the inflow surface 724. In an embodiment, the solid precursor 120 may be formed in a support container 214. A contact area of the solid precursor 120 with the carrier gas 18 may be increased by the exposed inflow surface 724. As the contact area increases, more solid precursors 120 may be sublimated by the carrier gas 18.

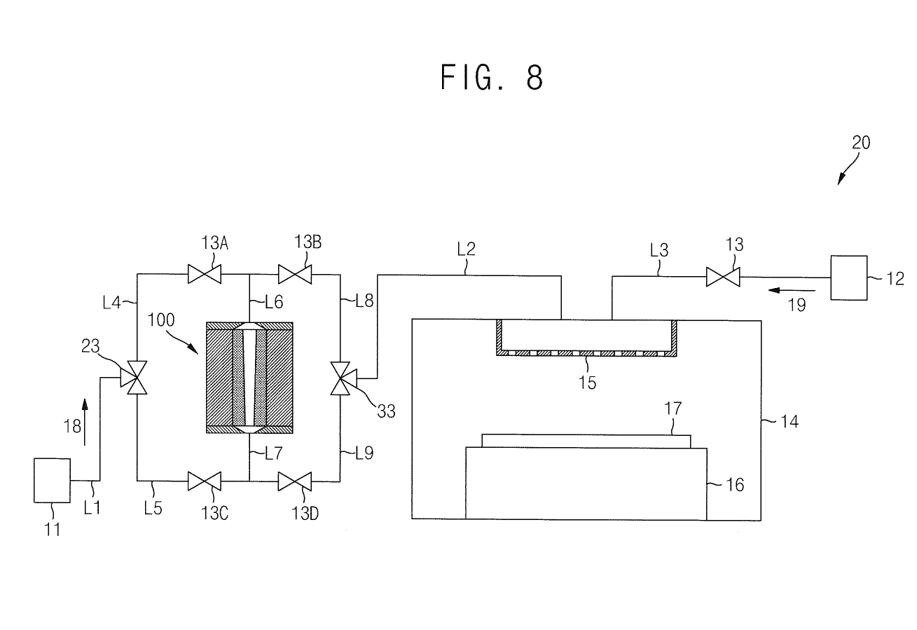

FIG. 8 is a schematic diagram a precursor delivery system 20 according to an embodiment of the present inventive concept.

Referring to FIG. 8, the precursor delivery system 20 may include three-way valves 23 and 33, fourth to ninth supply lines L4 to L9, and gate valves 13A, 13B, 13C, and 13D. The three-way valve 23 may be a diverting valve in which one inflow portion is connected to a first supply line L1 and two outflow portions are connected to the fourth and fifth supply lines L4 and L5. The three-way valve 33 may be a mixing valve in which two inflow portions are connected to the eighth and ninth supply lines L8 and L9 and one outflow portion is connected to a second supply line L2.

A carrier gas supply 11 may supply a carrier gas 18 through the first supply line L1. The carrier gas 18 may be supplied to the fourth supply line L4 and the fifth supply line L5 by the three-way valve 23. The carrier gas 18 supplied to the fourth supply line L4 or the fifth supply line L5 may be saturated with a gaseous precursor through a source gas supply unit 100. The carrier gas 18 discharged through the source gas supply unit 100 may be supplied into a processing chamber 14 through the eighth supply line L8 or the ninth supply line L9, the three-way valve 33, and the second supply line L2.

In an embodiment, the gate valves 13A and 13D may be in an open state, and the gate valves 13B and 13C may be in a closed state. The carrier gas 18 supplied from the carrier gas supply 11 may be supplied into the processing chamber 14 through the first supply line L1, the three-way valve 23, the fourth supply line L4, the sixth supply line L6, the source gas supply unit 100, the seventh supply line L7, the ninth supply line L9, the three-way valve 33, and the second supply line L2.

In an embodiment, the gate valves 13B and 13C may be in an open state, and the gate valves 13A and 13D may be in a closed state. The carrier gas 18 supplied from the carrier gas supply 11 may be supplied into the processing chamber 14 through the first supply line L1, the three-way valve 23, the fifth supply line L5, the seventh supply line L7, the source gas supply unit 100, the sixth supply line L6, the eighth supply line L8, the three-way valve 33, and the second supply line L2.

A direction of the carrier gas 18 at each of the sixth and seventh supply lines L6 and L7 and the source gas supply unit 100 is changed according to open or closed states of the gate valves 13A, 13B, 13C, and 13D. The direction of the carrier gas 18 may be changed during a deposition process. The relatively large erosion of the solid precursor 120 at a gas inlet 132 may be compensated by adjusting the direction of the carrier gas 18.

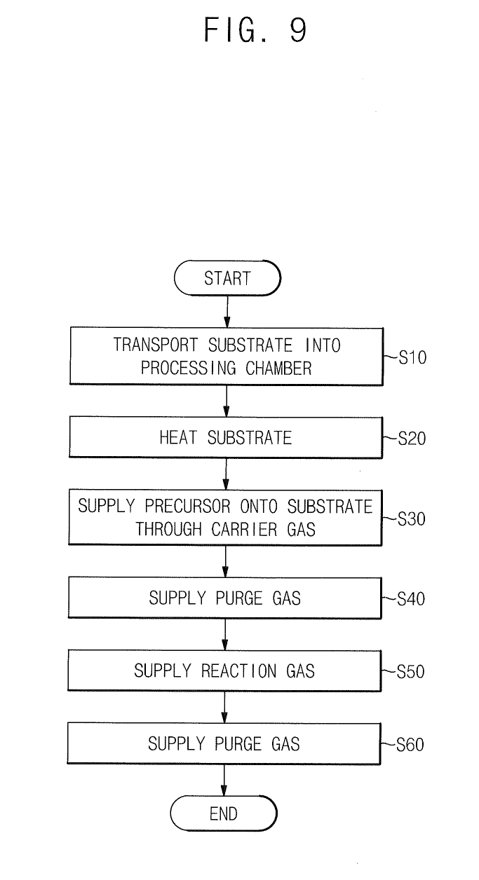

FIG. 9 is a flowchart for describing a method of forming a thin film using the source gas supply unit 100 of the present inventive concept.

Referring to FIG. 9, the method of forming a thin film includes transporting the substrate 17 into the processing chamber 14 (S10), heating the substrate 17 (S20), supplying a precursor (S30), supplying a purge gas (S40), supplying a reaction gas 19 (S50), and supplying a purge gas (S60). The method of forming a thin film may include a CVD method or an ALD method.

First, the substrate 17 is transported into the processing chamber 14 through an opening (not illustrated). The substrate 17 transported into the processing chamber 14 may be disposed on a susceptor 16 (S10).

Next, the transported substrate 17 is heated to an appropriate temperature to efficiently deposit a thin film (S20). In the heating of the substrate, an inside of the processing chamber 14 may also be heated.

A carrier gas supply 11 supplies a carrier gas 18 to a source gas supply unit 100. The carrier gas 18 supplied to the source gas supply unit 100 is saturated with a sublimated precursor. The carrier gas 18 containing the precursor is supplied into the processing chamber 14 (S30). The supplied carrier gas 18 may be provided onto the substrate 17 through a shower head assembly 15. The precursor on the substrate 17 may form a single layer.

A purge gas is supplied into the processing chamber 14 to remove the precursor and reactants thereof (S40). The purge gas may include an inert gas, and may be supplied into the processing chamber 14 through a different route from that of the carrier gas 18. The purge gas may be discharged to the outside of the processing chamber 14 through an exhaust port.

Next, the reaction gas 19 is supplied from a reaction gas supply 12 to the processing chamber 14 (S50). The reaction gas 19 may be provided onto the substrate 17 through the shower head assembly 15. The reaction gas 19 may react with the precursor to deposit a thin film.

The purge gas is then supplied into the processing chamber 14 to remove the reaction gas and reactants thereof (S60). The purge gas may be discharged to the outside of the processing chamber 14 through the exhaust port. The supplying of the carrier gas 18, the purge gas, and the reaction gas 19 (S30, S40, S50, and S60) may be repeatedly performed until the thin film is deposited to have a predetermined thickness.

According to the embodiments of the present inventive concept, a cross-sectional area of a gas flow path at a gas inlet can be narrowly formed to compensate for a high erosion amount of a solid precursor at the gas inlet.

According to the embodiments of the present inventive concept, a solid precursor can be formed to have a large contact area with a carrier gas, and a surface area can be increased with erosion so that reduction of a sublimation amount of a precursor due to reduction of a pressure of a gas can be compensated.

While the embodiments of the present inventive concept have been described with reference to the accompanying drawings, it will be understood by those skilled in the art that various modifications can be made without departing from the scope of the present inventive concept and without changing essential features thereof. Therefore, the above-described embodiments should be considered in a descriptive sense only and not for purposes of limitation.

What is claimed is:

1. A ring-shaped solid precursor for thin-film deposition comprising at least one gas flow path therein, wherein a cross-sectional area of the at least one gas flow path therein increases from an inflow surface of the ring-shaped solid precursor toward an outflow surface thereof.

2. The ring-shaped solid precursor of claim 1, wherein the at least one gas flow path has a shape in which a cross-sectional area thereof gradually increases from the inflow surface of the ring-shaped solid precursor toward the outflow surface thereof.

3. The ring-shaped solid precursor of claim 1, wherein the at least one gas flow path further comprises at least one ring-shaped trench formed in a direction perpendicular to the gas flow path.

4. The ring-shaped solid precursor of claim 1, wherein the at least one gas flow path has a shape in which a cross-sectional area thereof increases stepwise from the inflow surface of the ring-shaped solid precursor toward the outflow surface thereof.

5. The ring-shaped solid precursor of claim 1, wherein the ring-shaped solid precursor is formed from a stack of a plurality of unit blocks, wherein each unit block comprises a hollow therein, and
wherein the hollows from each unit block form the at least one gas flow path.

6. A source gas supply unit, comprising:
a canister comprising a precursor accommodating space therein, and an inflow surface and an outflow surface which are open;
a first lid comprising including a gas inlet connected to the precursor accommodating space, wherein the first lid is configured to seal the inflow surface of the canister;
a second lid comprising a gas outlet connected to the precursor accommodating space, wherein the second lid is configured to seal the outflow surface of the canister; and
the ring-shaped solid precursor of claim 1 disposed in the precursor accommodating space, wherein the at least one gas flow path therein is in communication with the gas inlet and the gas outlet.

7. The source gas supply unit of claim 6, wherein:
an inner side of the gas inlet of the first lid has a greater dimension than that of an outer side of the gas inlet; and
an inner side of the gas outlet of the second lid has a greater dimension than that of an outer side of the gas inlet.

8. The source gas supply unit of claim 7, wherein:
an inflow surface of the ring-shaped solid precursor faces the inner side of the gas inlet; and
an outflow surface of the ring-shaped solid precursor faces the inner side of the gas outlet.

9. The source gas supply unit of claim 6, further comprising a support container located in the precursor accommodating space of the canister, wherein the support container is configured to surround an outer circumferential surface of the ring-shaped solid precursor.

10. The source gas supply unit of claim 9, further comprising a supporting member coupled to the ring-shaped solid precursor on an inner circumferential surface of the support container.

11. The source gas supply unit of claim 6, wherein:
a gas inlet pipe is connected to an outer side of the gas inlet;
a gas outlet pipe is connected to an outer side of the gas outlet; and
the source gas supply unit further includes a filter configured to prevent particles of the ring-shaped solid precursor from being discharged into the gas inlet pipe and the gas outlet pipe.

12. A deposition device comprising:
a source gas supply unit;
a processing chamber configured to accommodate a substrate;
a source gas supply unit configured to supply a precursor to the processing chamber;
a carrier gas supply configured to supply a carrier gas to the source gas supply unit; and
a reaction gas supply configured to supply a reaction gas to the processing chamber,
wherein the source gas supply unit comprises:
a canister comprising a precursor accommodating space therein, and an inflow surface and an outflow surface which are open;
a first lid comprising a gas inlet connected to the precursor accommodating space, wherein the first lid is configured to seal the inflow surface of the canister;
a second lid comprising a gas outlet connected to the precursor accommodating space, wherein the second lid is configured to seal the outflow surface of the canister; and
the ring-shaped solid precursor of claim 1 disposed in the precursor accommodating space, wherein the at least one gas flow path therein is in communication with the gas inlet and the gas outlet.

13. The deposition device of claim 12, wherein:
the carrier gas supply supplies a carrier gas to the source gas supply unit through a first supply line;
the source gas supply unit delivers the carrier gas and the precursor to the processing chamber through a second supply line;
the reaction gas supply supplies a reaction gas to the processing chamber through a third supply line; and
gate valves provided at the first to third supply lines to adjust flow rates of the carrier gas and the reaction gas.

14. A source gas supply unit, comprising:
a canister comprising a precursor accommodating space therein, and an inflow surface and an outflow surface which are open;
a first lid comprising a gas inlet connected to the precursor accommodating space, wherein the first lid is configured to seal the inflow surface of the canister;
a second lid comprising a gas outlet connected to the precursor accommodating space, wherein the second lid is configured to seal the outflow surface of the canister; and
a ring-shaped solid precursor disposed in the precursor accommodating space, wherein the ring-shaped solid precursor comprises a gas flow path therein in communication with the gas inlet and the gas outlet,
wherein the gas flow path has a cylindrical shape,
an inflow surface of the ring-shaped solid precursor faces an inner side of the gas inlet,
an outflow surface of the ring-shaped solid precursor faces an inner side of the gas outlet, and
cross-sectional areas of the inner sides of the gas inlet and the gas outlet are formed to be wider than a cross-sectional area of the gas flow path so that the inflow surface and the outflow surface of the ring-shaped solid precursor are exposed to a carrier gas.

15. The source gas supply unit of claim 14, wherein:
an inner side of the gas inlet of the first lid has a greater dimension than that of an outer side of the gas inlet; and
an inner side of the gas outlet of the second lid has a greater dimension than that of an outer side of the gas outlet.

16. The source gas supply unit of claim 14, wherein the gas flow path further comprises a ring-shaped trench formed in a direction perpendicular to a movement direction of the carrier gas.

17. The source gas supply unit of claim 14, further comprising a support container located in the precursor accommodating space of the canister, wherein the support container is configured to surround an outer circumferential surface of the ring-shaped solid precursor.

18. The source gas supply unit of claim 17, further comprising a supporting member coupled to the ring-shaped solid precursor on an inner circumferential surface of the support container.

19. The source gas supply unit of claim 14, further comprising a plurality of unit blocks located in the precursor accommodating space and each comprising a hollow therein,
wherein the plurality of unit blocks are stacked to form the ring-shaped solid precursor and wherein hollows of the plurality of unit blocks form gas flow path.

20. A deposition device comprising:
a source gas supply unit of claim 14;
a processing chamber configured to accommodate a substrate;
a source gas supply unit configured to supply a precursor to the processing chamber;
a carrier gas supply configured to supply a carrier gas to the source gas supply unit; and
a reaction gas supply configured to supply a reaction gas to the processing chamber.
